(19) United States
(12) Patent Application Publication
(10) Pub. No.: US 2006/0226005 A1
(43) Pub. Date: Oct. 12, 2006

(54) Aluminum-based sputtering targets

(75) Inventors: Katsutoshi Takagi, Kobe-shi (JP); Toshihiro Kugimiya, Kobe-shi (JP); Katsufumi Tomihisa, Kobe-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: Kabushiki Kaisha Kobe Seiko Sho (Kobe Steel, Ltd.), Kobe-shi (JP)

(21) Appl. No.: 11/377,266

(22) Filed: Mar. 17, 2006

(30) Foreign Application Priority Data
Jun. 15, 2005 (JP) 2005-175579
Apr. 12, 2005 (JP) 2005-114885

(51) Int. Cl. C23C 14/00

(52) U.S. Cl. 204/298.12

(57) ABSTRACT

An Al-based sputtering target mainly containing Al has a total number of concave defects having largest depths of 0.2 μm or more and equivalent area diameters of 0.2 μm or more of 45000 or less per square millimeter of unit surface area of a surface of the sputtering target corresponding to a sputtering plane. Another Al-based sputtering target has a total number of concave defects having largest depths of 0.1 μm or more and equivalent area diameters of 0.5 μm or more of 15000 or less per square millimeter of unit surface area on the surface. These sputtering targets are reduced in time period and number of sputtering failures (a splash and/or an arc) occurring in their use, particularly at an early stage of their use.

### BACKGROUND OF THE INVENTION

1. Field of the Invention

The present invention relates to aluminum-based (Al-based) sputtering targets. Specifically, it relates to Al-based sputtering targets mainly containing Al, such as sputtering targets of Al alloys or pure Al, and more specifically, it relates to Al-based sputtering targets in which the time period and number of sputtering failures (a splash and/or an arc) occurring at an early stage of their use are reduced.

2. Description of the Related Art

Aluminum-based thin films such as interconnection films, electrode films, and reflecting electrode films are deposited by sputtering using Al-based sputtering targets in the production of flat panel displays (FPDs). The flat panel displays include liquid crystal displays (LCDs) such as amorphous silicon TFT LCDs and polysilicon TFT LCDs; field emission displays (FEDs); electroluminescence displays (ELDs) such as organic ELDs and inorganic ELDs; and plasma display panels (PDPs).

When Al-based thin films are deposited by sputtering using Al-based sputtering targets, sputtering failures such as a splash and an arc often occur particularly at an early stage of their use, and defected portions caused by the sputtering failures typically in Al-based interconnection films, electrode films, and reflecting electrode films cause decreased yields and deteriorated operations and performance of FPDs.

To prevent sputtering failures at an early stage of use of sputtering targets for ITO (indium-tin oxide) thin films of transparent electrode films, the following five conventional techniques have been proposed.

[1] Surface treatment by laser in ITO sputtering targets (Japanese Laid-open (Unexamined) Patent Application Publication (JP-A) No. 2003-55762).

[2] Reduction of linear machining scars in ITO sputtering targets (JP-A No. 2003-73821).

[3] Surface treatment by sputtering in ITO sputtering targets (JP-A No. 2003-89869).

[4] Reduction of microcrack in ITO sputtering targets (JP-A No. 2003-183820).

[5] Surface treatment by a jet of water at a predetermined pressure in ITO sputtering targets (JP-A No. 2005-42169).

However, there has been no proposal for preventing sputtering failures in Al-based sputtering targets (sputtering targets mainly containing Al such as of Al alloys or pure Al) for use typically as interconnection films, electrode films, and reflecting electrode films of FPDs.

### SUMMARY OF THE INVENTION

Under these circumstances, an object of the present invention is to provide an Al-based sputtering target mainly containing Al in which the time period and number of occurrence of sputtering failures such as a splash and/or an arc particularly at an early stage of their use.

After intensive investigations to achieve the above objects, the present inventors have accomplished the present invention. The present invention can achieve the above objects.

The present invention thus accomplished relates to Al-based sputtering targets and provides Al-based sputtering target shaving the following configurations according to first and second aspects.

Specifically, the Al-based sputtering target according to the first aspect is an Al-based sputtering target mainly containing Al, in which, of concave defects defined as concave portions having largest depths of 0.1 μm or more and equivalent area diameters of 0.2 μm or more, the total number of concave defects having largest depths of 0.2 μm or more is 45000 or less per square millimeter of unit surface area of a surface of the sputtering target corresponding to a sputtering plane.

The Al-based sputtering target according to the second aspect is an Al-based sputtering target mainly containing Al, in which, of concave defects defined as concave portions having largest depths of 0.1 μm or more and equivalent area diameters of 0.2 μm or more, the total number of concave defects having equivalent area diameters of 0.5 μm or more is 15000 or less per square millimeter of unit surface area of a surface of the sputtering target corresponding to a sputtering plane.

According to the Al-based sputtering targets of the present invention, the time period and number of sputtering failures (a splash and/or an arc) occurring particularly at an early stage of their use can be reduced.

Further objects, features and advantages of the present invention will become apparent from the following description of the preferred embodiments with reference to the attached drawings.

### BRIEF DESCRIPTION OF THE DRAWINGS

FIG. 1 is a photograph showing an example of concave defects on a surface of an Al-based sputtering target caused by machining; and

FIG. 2 is a photograph showing an example of a surface of an Al-based sputtering target.

### DESCRIPTION OF THE PREFERRED EMBODIMENTS

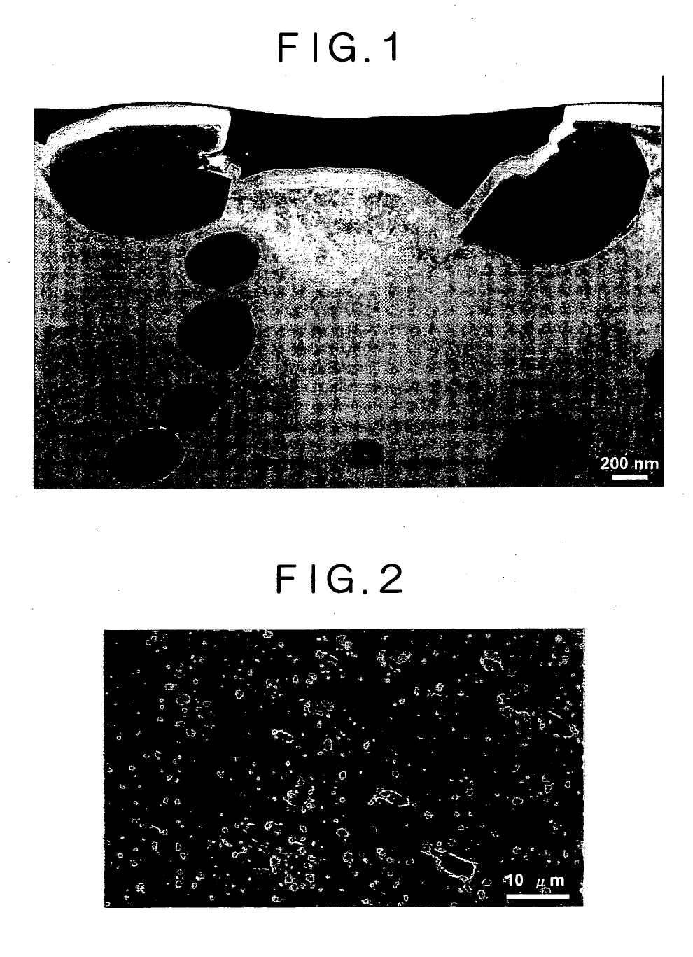

The “concave defects” in the Al-based sputtering targets according to the present invention are defined as concave portions having largest depths of 0.1 μm or more and equivalent area diameters of 0.2 μm or more. Some concave defects are formed because intermetallic compounds in the Al-based sputtering targets are pushed down by cutting tools such as milling machines and lathes upon machining. The causal relation between the concave defects and the sputtering failures (a splash and/or an arc) has not yet been known. An example of sectional transmission electron microscopic images of the concave defects is shown in FIG. 1.

The present inventors made intensive investigations about the relationships of the dimensions (largest depth and equivalent area diameter) and the total number per unit surface area of concave defects (density of concave defects) in a surface of the sputtering targets corresponding to a sputtering plane in Al-based sputtering targets mainly comprising Al with the time period and number of occurrence of sputtering failures (a splash and/or an arc) particularly at an early stage of use of the Al-based sputtering targets. As a result, they found that sputtering failures such as a splash and/or an arc are caused by (originated from) the concave defects, and they revealed that the time period and number of occurrence of a splash and/or an arc can be reduced by reducing the total number of concave defects per unit surface area (density of concave defects) to a specific level or less, which concave defects have largest depths and/or equivalent area diameters at specific levels or more. They also found that concave defects which may cause sputtering failures can be effectively reduced by reducing the depth of cut and feed speed in milling in the production of sputtering targets and found that the concave defects can be reduced to thereby reduce sputtering failures by reducing the depth of cut and feed speed. In contrast, in conventional technologies, milling is conducted at a large depth of cut and a high feed speed from the viewpoint of improving the productivity of sputtering targets, which invites a large quantity of concave defects and frequent occurrence of sputtering failures.

Specifically, the specific levels of the largest depth, equivalent area diameter, and density of concave defects are as follows. The specific level of largest depth is 0.2 μm, and the specific level of density of concave defects having largest depths of 0.2 μm or more is 45000. The specific level of the equivalent area diameter is 0.5 μm, and the specific level of density of concave defects having equivalent area diameters of 0.5 μm or more is 15000. In other words, the time period and number of occurrence of sputtering failures (a splash and/or an arc) particularly at an early stage of use of sputtering targets can be reduced when the total number of concave defects having largest depths of 0.2 μm or more is 45000 or less per square millimeter of unit surface area (the density of concave defects per square millimeter is 45000 or less) or when the total number of concave defects having equivalent area diameters of 0.5 μm or more is 15000 or less per square millimeter of unit surface area (the density of concave defects per square millimeter is 15000 or less).

The present invention has been achieved based on these findings. The Al-based sputtering targets according to the present invention include an Al-based sputtering target mainly comprising Al, wherein, of concave defects defined as concave portions having largest depths of 0.1 μm or more and equivalent area diameters of 0.2 μm or more, the total number of concave defects having largest depths of 0.2 μm or more is 45000 or less per square millimeter of unit surface area of a surface of the sputtering target corresponding to a sputtering plane. (the Al-based sputtering target according to the first embodiment); and Al-based sputtering target mainly comprising Al, wherein, of concave defects defined as concave portions having largest depths of 0.1 μm or more and equivalent area diameters of 0.2 μm or more, the total number of concave defects having equivalent area diameters of 0.5 μm or more is 15000 or less per square millimeter of unit surface area of a surface of the sputtering target corresponding to a sputtering plane (the Al-based sputtering target according to the second embodiment).

As is obvious from the above-mentioned findings, by using these Al-based sputtering targets (the Al-based sputtering targets according to the first and second embodiments), the time period and number of sputtering failures (a splash and/or an arc) occurring particularly at an early stage of their use of can be reduced. This prevents the formation of defected portions caused by sputtering failures typically in Al-based interconnection films, electrode films, and reflecting electrode films. Accordingly, reduced yields and failures in operations and performance of FPDs due to these defected portions can be prevented.

Of concave defects defined as concave portions having largest depths of 0.1 μm or more and equivalent area diameters of 0.2 μm or more in the Al-based sputtering target according to the first embodiment, the total number of concave defects having largest depths of 0.2 μm or more is 45000 or less per square millimeter of unit surface area, namely, the density of the concave defects is 45000 or less per square millimeter. If the total number of the concave defects having equivalent area diameters of 0.2 μm or more and largest depths of 0.2 μm or more exceeds 45000 per square millimeter of unit surface area, namely, if the density of concave defects having equivalent area diameters of 0.2 μm or more and largest depths of 0.2 μm or more exceeds 45000 per square millimeter, concave defects which cause sputtering failures are deep and are large in number. Accordingly, it takes a long time for a splash and/or an arc to disappear. Thus, the time period and number of occurrence of a splash and/or an arc, particularly the time period, is not reduced.

In the Al-based sputtering target according to the first embodiment, the density of concave defects having equivalent area diameters of 0.2 μm or more and largest depths of 0.2 μm or more is 45000 or less per square millimeter. This can reduce the time period and number of occurrence of sputtering failures (a splash and/or an arc). When the density of the concave defects is 40000 or less per square millimeter, the time period and number of occurrence of sputtering failures (a splash and/or an arc) can be reduced at a higher level. When the density of the concave defects is 35000 or less per square millimeter, or is 30000 or less per square millimeter, the time period and number of occurrence of sputtering failures can be reduced at a further higher level. From these viewpoints, the density of concave defects herein is preferably 40000 or less per square millimeter, more preferably 35000 or less per square millimeter, and further preferably 30000 or less per square millimeter.

In the Al-based sputtering target according to the second embodiment, of concave defects defined as concave portions having largest depths of 0.1 μm or more and equivalent area diameters of 0.2 μm or more, the total number of concave defects having equivalent area diameters of 0.5 μm or more is 15000 or less per square millimeter of unit surface area, namely, the density of the concave defects is 15000 or less per square millimeter. If the total number of the concave defects having largest depths of 0.1 μm or more and equivalent area diameters of 0.5 μm or more exceeds 15000 per square millimeter of unit surface area, namely, if the density of concave defects having largest depths of 0.1 μm or more and equivalent area diameters of 0.5 μm or more exceeds 15000 per square millimeter, concave defects which cause sputtering failures have larger sizes and are large in number. Accordingly, the number and time period of occurrence of a splash and/or an arc, particularly the number is not reduced.

The Al-based sputtering target according to the second embodiment has a density of the concave defects having largest depths of 0.1 μm or more and equivalent area diameters of 0.5 μm or more of 15000 or less per square millimeter. This can reduce the time period and number of occurrence of sputtering failures (a splash and/or an arc). When the density of the concave defects is 12000 or less per square millimeter, the time period and number of occurrence of sputtering failures (a splash and/or an arc) can be reduced at a higher level. When the density of the concave defects is 10000 or less per square millimeter, or is 5000 or less per square millimeter, the time period and number of occurrence of sputtering failures can be reduced at a further higher level. From these viewpoints, the density of the concave defects herein is preferably 12000 or less per square millimeter, more preferably 10000 or less per square millimeter, and further preferably 5000 or less per square millimeter.

Base materials for the Al-based sputtering targets according to the present invention can be produced by any method such as melting-casting, powder sintering, or spray forming. Of these production methods, spray forming is preferred. Al-based sputtering targets produced by spray forming have less contents of impurities such as oxygen and include uniform and fine crystal grains and uniformly dispersed alloying elements, as compared with products produced by the other methods.

The Al-based sputtering targets according to the present invention may be produced by milling thus-prepared base materials while controlling the depth of cut and the feed speed of Al-based sputtering targets. More specifically, the depth of cut in milling is preferably set at 1.0 mm or less. If it exceeds 1.0 mm, the total number of concave defects which cause sputtering failures (a splash and/or an arc) may be large, and the number and time period of occurrence of a splash and/or an arc may not be reduced. The feed speed is preferably set at 3000 mm/min or less. If it exceeds 3000 mm/min, the total number of concave defects which cause sputtering failures (a splash and/or an arc) may be large, and the number and time period of occurrence of a splash and/or an arc may not be reduced. A balance between the depth of cut and the feed speed is preferably stroke, in addition to setting these parameters within the above-specific ranges. For example, when the depth of cut is 1.0 mm or less but more than 0.5 mm, the feed speed is preferably set at less than 1000 mm/min. When the feed speed is 3000 mm/min or less but more than 1000 mm/min, the depth of cut is preferably set at less than 0.5 mm. From the viewpoint of reduction of the time period and number of occurrence of sputtering failures in the present invention, the lower limits of the depth of cut and feed speed may not necessarily set. However, for satisfactory productivity of Al-based sputtering targets, the depth of cut and feed speed are preferably set at 0.01 mm or more and 200 mm/min or more, respectively.

In the present invention, the term “largest depth” of a concave defect refers to a distance (depth) from the outermost surface of a sputtering target to the deepmost point (bottom) of the concave defect. The term “equivalent area diameter” of a concave defect refers to, when the upper opening of a concave defect (hole) (opening at the outermost surface of a sputtering target) is circle, the diameter of the circle. In the other cases, it refers to the diameter (d) of a circle having the same area as the area (S) of the upper opening and, more specifically, it refers to ”d” satisfying (determined by) the following equation: S=π×(d/2)².

The “number of occurrence of sputtering failures (a splash and/or an arc)” refers to the number of occurrence of a splash and/or an arc. The number of occurrence of splashes refers to the number of splashes on a silicon wafer substrate measured with a wafer surface tester. The number of arcs refers to the number of arcs measured with a micro arc monitor. The time period of occurrence of sputtering failures (a splash and/or an arc) refers to the time period during which a splash and/or an arc occurs. More specifically, it refers to the time period from the beginning of use of a sputtering target to the disappearance of a splash and/or an arc.

### EXAMPLES

The present invention will be illustrated in further detail with reference to several Examples and Comparative Examples below. It is to be noted that the followings are only examples which by no means limit the scope of the present invention, and various changes and modifications are possible therein without departing from the teaching and scope of the present invention.

A preform (base material) comprising an Al-2 at % Nd alloy was produced by spray forming. The preform was encapsulated in a capsule, and the capsule was evacuated and subjected to hot isostatic pressing (HIP). The Al-2 at % Nd alloy material refined by HIP was subjected to hot forging, hot rolling, cold rolling, and heat treatment and thereby yielded an Al-2 at % Nd alloy sheet.

The thus-obtained Al-2 at % Nd alloy plate was subjected to milling under different conditions at depths of cut of 0.1 to 1.0 mm and feed speeds of 400 to 3000 mm/min and thereby yielded a series of Al-2 at % Nd alloy plates having different concave defects. By punching these plates, disc-form Al-2 at % Nd alloy sputtering targets having a diameter of 101.6 mm and a thickness of 5.0 mm were produced.

Arbitrary five visual fields (area per one visual field: 55 μm×78 μm=4290 μm²) on surface of each of the Al-2 at % Nd alloy sputtering targets were observed and photographs were taken with a scanning electron microscope (SEM) at a magnification of 1500 times. The SEM photographs of the respective visual fields were analyzed with an image analysis software (analySIS auto; Soft Imaging System GmbH) to determine the equivalent area diameters of concave defects and the total number per unit surface area (density of concave defects) of concave defects having equivalent area diameters of 0.5 μm or more, and the average of densities of concave defects in the five visual fields was defined as the density of concave defects of the tested sputtering target. Additionally, arbitrary five visual fields (area per one visual field: 300 μm×300 μm=90000 μm² on surface of each of the Al-2 at % Nd alloy sputtering targets were observed and three-dimensional images were taken with a laser microscope. The three-dimensional images of the individual visual fields were analyzed to determine the largest depths of concave defects and the total number per unit surface area (density of concave defects) of concave defects having largest depths of 0.2 μm or more, and the average of densities of concave defects of the five visual fields was defined as the density of concave defects of the tested sputtering target. An example of the SEM images of surfaces of the sputtering targets is shown in FIG. 2.

Furthermore, silicon wafer substrates having a diameter of 100.0 mm and a thickness of 0.50 mm were subjected to DC magnetron sputtering using the Al-2 at % Nd alloy sputtering targets at a base pressure of 3.0×10^{-31 6} Torr or less, an argon gas pressure of 2.25 mTorr, an argon gas flow rate of 30 sccm, a sputtering power of 811 W, a target-to-substrate distance of 51.6 mm, and a substrate temperature of room temperature. The position coordinates, sizes, and numbers of particles on the resulting silicon wafers were determined using a particle counter (the wafer surface analyzer WM-3; TOPCON CORPORATION). By observing the silicon wafers with an optical microscope based on the determined data, splashes (particles having semispherical shapes) were measured and classified to thereby determine the time period and the number of occurrence of splashes. Specifically, DC magnetron sputtering was continuously conducted on each silicon wafer for 81 seconds per silicon wafer while sequentially exchanging the wafers. In the resulting silicon wafers, the integrated time of sputtering until a silicon wafer showing no a splash was produced was defined as the time period of occurrence of a splash, and the number of splashes per unit surface area of the silicon wafers was defined as the number of occurrence of a splash. Arcs occurring during the DC magnetron sputtering were measured using an arc monitor (the Micro Arc Monitor MAM Genesis; Landmark Technology Co., Ltd.) connected to an electric circuit of a sputtering system (the Sputtering System HSR-542S; Shimadzu Corporation), and the time period and number of occurrence of arcs were determined. Specifically, the integrated sputtering time until an arc disappeared was defined as the time period of occurrence of an arc, and the total integrated number of arcs within the time period of occurrence of an arc was defined as the number of occurrence of an arc. The samples having a time period of occurrence of a splash of 10 minutes or more, a time period of occurrence of an arc of 10 minutes or more, a number of occurrence of a splash of 10 or more per square centimeter, or a number of occurrence of an arc of 100 or more were evaluated as “poor” in sputtering failure inhibition, and the other samples were evaluated as “excellent” in sputtering failure inhibition.

The results are shown in Tables 1 to 4. Table 1 shows the relationship between the number of concave defects having largest depths of 0.2 μm or more per square millimeter of unit surface area (the density of concave defects per square millimeter) and the time period of occurrence of a splash with the sputtering failure inhibition. Table 2 shows the relationship between the number of concave defects having largest depths of 0.2 μm or more per square millimeter of unit surface area (density of concave defects per square millimeter) and the time period of occurrence of an arc with the sputtering failure inhibition. Table 3 shows the relationship between the number of concave defects having equivalent area diameters of 0.5 μm or more per square millimeter of unit surface area (density of concave defects per square millimeter) and the number of occurrence of a splash with the sputtering failure inhibition. Table 4 shows the relationship between the number of concave defects having equivalent area diameters of 0.5 μm or more per square millimeter of unit surface area (density of concave defects per square millimeter) and the number of occurrence of an arc with the sputtering failure inhibition.

Table 1 demonstrates that the samples of Nos. 5 and 8 (Comparative Examples) have long time periods of occurrence of a splash and are poor in sputtering failure inhibition (indicated by “Poor” in Table 1). In contrast, the samples of Nos. 1 to 4, 6, and 7 (Examples) have very short time periods of occurrence of a splash and are excellent in sputtering failure inhibition (indicated by “Excellent” in Table 1).

Table 2 demonstrates that the samples of Nos. 5 and 8 (Comparative Examples) have long time periods of occurrence of an arc and are poor in sputtering failure inhibition (indicated by “Poor” in Table 2). In contrast, the samples of Nos. 1 to 4, 6, and 7 (Examples) have very short time periods of occurrence of an arc and are excellent in sputtering failure inhibition (indicated by “Excellent” in Table 2).

Table 3 demonstrates that the sample of No. 8 (Comparative Example) has a large number of occurrence of a splash and is poor in sputtering failure inhibition (indicated by “Poor” in Table 3). In contrast, the samples of Nos. 1 to 4, 6, and 7 (Examples) have very small numbers of occurrence of a splash and are excellent in sputtering failure inhibition (indicated by “Excellent” in Table 3).

Table 4 demonstrates that the sample of No. 8 (Comparative Example) has a large number of occurrence of an arc and is poor in sputtering failure inhibition (indicated by “Poor” in Table 4). In contrast, the samples of Nos. 1 to 4, 6, and 7 (Examples) have very small numbers of occurrence of an arc and are excellent in sputtering failure inhibition (indicated by “Excellent” in Table 4).

In short, the samples of Nos. 5 and 8 (Comparative Examples) have long time periods of occurrence of a splash and long time periods of occurrence of an arc, and the sample of No. 8 has a large number of occurrence of a splash and a large number of occurrence of an arc, and they are poor in sputtering failure inhibition. In contrast, the samples of Nos. 1 to 4, 6, and 7 (Examples) have very short time periods of occurrence of a splash, very short time periods of occurrence of an arc, very small numbers of occurrence of a splash, and very small numbers of occurrence of an arc and are excellent in sputtering failure inhibition.

TABLE 1

| | | Feed speed | | Density of concave | Time period of | Sputtering | |
|---|---|---|---|---|---|---|---|
| | Depth of cut | in milling | Largest depth of | defects per square | occurrence of | failure | |
| No. | in milling (mm) | (mm/min) | concave defects | millimeter | a splash (min) | inhibition | Remarks |
| 1 | 0.1 | 500 | 0.2 μm | 25874 | 2 | Excellent | Example |
| | | | or more | | | | |
| 2 | 0.2 | 500 | 0.2 μm | 30536 | 3 | Excellent | Example |
| | | | or more | | | | |
| 3 | 0.5 | 500 | 0.2 μm | 34965 | 5 | Excellent | Example |
| | | | or more | | | | |
| 4 | 1.0 | 500 | 0.2 μm | 44755 | 9 | Excellent | Example |
| | | | or more | | | | |
| 5 | 1.0 | 1000 | 0.2 μm | 50210 | 21 | Poor | Comparative |
| | | | or more | | | | Example |
| 6 | 0.2 | 400 | 0.2 μm | 25175 | 2 | Excellent | Example |
| | | | or more | | | | |
| 2 | 0.2 | 500 | 0.2 μm | 30536 | 3 | Excellent | Example |
| | | | or more | | | | |
| 7 | 0.2 | 1000 | 0.2 μm | 35198 | 6 | Excellent | Example |
| | | | or more | | | | |
| 8 | 0.2 | 3000 | 0.2 μm | 49417 | 20 | Poor | Comparative |
| | | | or more | | | | Example |

TABLE 2

| | | Feed speed | | Density of concave | Time period of | Sputtering | |
|---|---|---|---|---|---|---|---|
| | Depth of cut | in milling | Largest depth of | defects per square | occurrence of | failure | |
| No. | in milling (mm) | (mm/min) | concave defects | millimeter | an arc (min) | inhibition | Remarks |
| 1 | 0.1 | 500 | 0.2 μm | 25874 | 1 | Excellent | Example |
| | | | or more | | | | |
| 2 | 0.2 | 500 | 0.2 μm | 30536 | 2 | Excellent | Example |
| | | | or more | | | | |
| 3 | 0.5 | 500 | 0.2 μm | 34965 | 3 | Excellent | Example |
| | | | or more | | | | |
| 4 | 1.0 | 500 | 0.2 μm | 44755 | 9 | Excellent | Example |
| | | | or more | | | | |
| 5 | 1.0 | 1000 | 0.2 μm | 50210 | 18 | Poor | Comparative |
| | | | or more | | | | Example |
| 6 | 0.2 | 400 | 0.2 μm | 25175 | 1 | Excellent | Example |
| | | | or more | | | | |
| 2 | 0.2 | 500 | 0.2 μm | 30536 | 2 | Excellent | Example |
| | | | or more | | | | |
| 7 | 0.2 | 1000 | 0.2 μm | 35198 | 3 | Excellent | Example |
| | | | or more | | | | |
| 8 | 0.2 | 3000 | 0.2 μm | 49417 | 18 | Poor | Comparative |
| | | | or more | | | | Example |

TABLE 3

| | | | | | Number of | | |
|---|---|---|---|---|---|---|---|
| | | Feed speed | Equivalent area | Density of concave | occurrence of a | Sputtering | |
| | Depth of cut | in milling | diameter of | defects per square | splash (per | failure | |
| No. | in milling (mm) | (mm/min) | concave defects | millimeter | square centimeter) | inhibition | Remarks |
| 1 | 0.1 | 500 | 0.5 μm | 3497 | 4 | Excellent | Example |
| | | | or more | | | | |
| 2 | 0.2 | 500 | 0.5 μm | 5128 | 5 | Excellent | Example |
| | | | or more | | | | |
| 3 | 0.5 | 500 | 0.5 μm | 9091 | 6 | Excellent | Example |
| | | | or more | | | | |
| 4 | 1.0 | 500 | 0.5 μm | 14219 | 8 | Excellent | Example |
| | | | or more | | | | |
| 6 | 0.2 | 400 | 0.5 μm | 3730 | 4 | Excellent | Example |
| | | | or more | | | | |
| 2 | 0.2 | 500 | 0.5 μm | 5128 | 5 | Excellent | Example |
| | | | or more | | | | |
| 7 | 0.2 | 1000 | 0.5 μm | 9324 | 7 | Excellent | Example |
| | | | or more | | | | |
| 8 | 0.2 | 3000 | 0.5 μm | 16550 | 13 | Poor | Comparative |
| | | | or more | | | | Example |

TABLE 4

| | | | Equivalent area | Density of concave | Number of | Sputtering | |
|---|---|---|---|---|---|---|---|
| | Depth of cut | Feed speed | diameter of concave | defects per square | occurrence | failure | |
| No. | in milling (mm) | in milling (mm/min) | defects | millimeter | of an arc | inhibition | Remarks |
| 1 | 0.1 | 500 | 0.5 μm | 3497 | 33 | Excellent | Example |
| | | | or more | | | | |
| 2 | 0.2 | 500 | 0.5 μm | 5128 | 47 | Excellent | Example |
| | | | or more | | | | |
| 3 | 0.5 | 500 | 0.5 μm | 9091 | 57 | Excellent | Example |
| | | | or more | | | | |
| 4 | 1.0 | 500 | 0.5 μm | 14219 | 86 | Excellent | Example |
| | | | or more | | | | |
| 6 | 0.2 | 400 | 0.5 μm | 3730 | 35 | Excellent | Example |
| | | | or more | | | | |
| 2 | 0.2 | 500 | 0.5 μm | 5128 | 47 | Excellent | Example |
| | | | or more | | | | |
| 7 | 0.2 | 1000 | 0.5 μm | 9324 | 58 | Excellent | Example |
| | | | or more | | | | |
| 8 | 0.2 | 3000 | 0.5 μm | 16550 | 121 | Poor | Comparative |
| | | | or more | | | | Example |

The Al-based sputtering targets according to the present invention can have reduced time periods and numbers of sputtering failures (a splash and/or an arc) occurring particularly at an early stage of their use, can therefore be advantageously used as Al-based sputtering targets typically for depositing Al-based interconnection films, electrode films, and reflecting electrode films. The sputtering targets can prevent occurrence of defects in these films and thereby avoid decrease of yields and occurrence of deteriorated operation and performance of FPDs.

What is claimed is:

1. An Al-based sputtering target mainly comprising Al, wherein, of concave defects defined as concave portions having largest depths of 0.1 μm or more and equivalent area diameters of 0.2 μm or more, the total number of concave defects having largest depths of 0.2 μm or more is 45000 or less per square millimeter of unit surface area of a surface of the sputtering target corresponding to a sputtering plane.

2. An Al-based sputtering target mainly comprising Al, wherein, of concave defects defined as concave portions having largest depths of 0.1 μm or more and equivalent area diameters of 0.2 μm or more, the total number of concave defects having equivalent area diameters of 0.5 μm or more is 15000 or less per square millimeter of unit surface area of a surface of the sputtering target corresponding to a sputtering plane.
